(19) United States
(12) Patent Application Publication
(10) Pub. No.: US 2021/0272638 A1
(43) Pub. Date: Sep. 2, 2021

(54) REDUCED-PASS ERASE VERIFY FOR NONVOLATILE STORAGE MEDIA

(71) Applicant: Intel Corporation, Santa Clara, CA (US)

(72) Inventors: Chunyuan HOU, Shanghai (CN); Ke LIANG, Shanghai (CN); Jun XU, Shanghai (CN); Si LI, Shanghai (CN)

(21) Appl. No.: 17/253,095

(22) PCT Filed: Dec. 25, 2018
(86) PCT No.: PCT/CN2018/123344

§ 371 Date: Dec. 16, 2020

(51) Int. Cl. G11C 16/34; G11C 16/16; G11C 16/26; G11C 16/30; G11C 16/08

(52) U.S. Cl. CPC G11C 16/3445; G11C 16/3477; G11C 16/08; G11C 16/26; G11C 16/30; G11C 16/16

(57) ABSTRACT

A storage array includes multiple wordlines of storage cells that can be selectively charged to an erase voltage or an inhibit voltage. Control logic associated with the storage array can perform erase verify in stages. On a first erase verify pass, the control logic can set wordlines of an erase block or subblock to a first erase voltage. On a second erase verify pass, the control logic can trigger a second erase verify pulse and set passing wordlines to an inhibit voltage, and failing wordlines to a second erase voltage higher than the first voltage. Inhibiting the already passing wordlines can reduce threshold voltage differences among the wordlines.

### CLAIM OF PRIORITY

This application is a U.S. National Phase application under 35 U.S.C. § 371 of International Application No. PCT/CN18/123344 filed Dec. 25, 2018, entitled “REDUCED-PASS ERASE VERIFY FOR NONVOLATILE STORAGE MEDIA” the entire contents of which are incorporated herein by reference.

### FIELD

Descriptions are generally related to nonvolatile memory devices, and more particular descriptions relate to erase operation for storage devices.

### BACKGROUND

Certain nonvolatile memory devices, such as NAND-based storage, performs an erase to reclaim blocks of storage. The erase is typically followed by an erase verify to ensure that the erase has resulted in storage cells being properly erased. If a wordline fails the erase verify, the system can make another erase pass until all erased wordlines pass the erase verify.

However, not all wordlines will pass the erase at the same time. The variation in passing the erase verify can be due to a variety of factors that can include different operating conditions (e.g., temperature, voltage level), process variations in manufacturing, difference in use (i.e., different numbers of write and erase cycles the cell has experienced), or other factors, or a combination. A wordline will traditionally be erased again if another wordline in its erase block failed to pass on a previous erase pass. Thus, wordlines are traditionally subjected to additional erase cycles until the worst case erase is verified.

The additional erase passes are typically performed at a higher voltage. Additional erases of a wordline or subblock that has already passed erase verify increase the erase stress on the storage cells of the wordlines/subblocks that already passed. Erasing a subblock that has already passed results in a “deeper” erase of the subblock, which causes the Vt for that subblock to be lower. Programming cells places the cell Vt to the program Vt (or PV). The PV level is fixed, so a deeper erase that results in a lower starting Vt sees a larger Vt shift. Due to cell coupling, a larger Vt shift will result in more coupling to adjacent cell, which induces a larger error for the Vt of the adjacent cells.

### BRIEF DESCRIPTION OF THE DRAWINGS

The following description includes discussion of figures having illustrations given by way of example of an implementation. The drawings should be understood by way of example, and not by way of limitation. As used herein, references to one or more examples are to be understood as describing a particular feature, structure, or characteristic included in at least one implementation of the invention. Phrases such as “in one example” or “in an alternative example” appearing herein provide examples of implementations of the invention, and do not necessarily all refer to the same implementation. However, they are also not necessarily mutually exclusive.

FIG. 1A is a block diagram of an example of a system having a memory device in which an erase verify can be performed in stages with selective wordline inhibit.

FIG. 1B is a block diagram of an example of a circuit structure for the system of FIG. 1A.

FIG. 2 is a block diagram of an example of a memory device subblock architecture.

FIG. 3 is a diagram of an example of erase voltage distribution.

FIG. 4 is a flow diagram of an example of a process for providing erase verify with inhibit for passed subblocks.

FIG. 5A is a flow diagram of an example of a process for providing erase verify with inhibit for passed wordlines with separate even and odd erase verify passes.

FIG. 5B is a flow diagram of an example of a process for providing erase verify with passing wordline inhibit, with separate even and odd wordline erase verify passes.

FIG. 6 is a diagrammatic representation of an embodiment of voltage waveforms in a system that provides wordline or subblock inhibit in for different stages of erase verify.

FIG. 7 is a block diagram of an example of a computing system in which erase verify with wordline or subblock inhibit can be implemented.

FIG. 8 is a block diagram of an example of a mobile device in which erase verify with wordline or subblock inhibit can be implemented.

Descriptions of certain details and implementations follow, including non-limiting descriptions of the figures, which may depict some or all examples, and well as other potential implementations.

### DETAILED DESCRIPTION

As described herein, a storage array includes multiple wordlines of storage cells that are erased in stages with increasing erase voltage. Control logic associated with the storage array can perform erase verify with multiple erase passes, increasing the erase voltage on each pass. Instead of performing the erase operation on wordlines that have already passed, the control logic can apply an inhibit voltage for subsequent erase passes to prevent performing the erase operations on passing subblocks or wordlines. On a first erase verify pass, the control logic can set an erase block or subblock to a first erase voltage. On a second erase verify pass, the control logic can trigger a second erase pulse and set the inhibit voltage for passing subblocks or wordlines, and set a second erase voltage higher than the first erase voltage for failing wordlines. Inhibiting the wordlines that already passed can reduce threshold voltage (Vt) spread for the wordlines.

In one example, the system applies a voltage to a wordline to erase the storage cells of the wordline. The erase operation can be considered to include the erasing of the storage cells and the erase verify to ensure that the storage cells were actually erased. The erase operation could alternatively be considered the application of the voltage to the wordline to erase the storage cells, and the erase verify can be considered a separate operation. The complete erase and erase verify can be referred to as an erase algorithm that the system performs.

In one example, the erase verify is performed at the level of a 3D (three dimensional) NAND (not AND) subblock. A subblock refers to a group of storage cells that can be activated together. For example, a subblock can include multiple columns of a 3D or stacked storage device that share or respond to a common signal. In a system that performs erase verify at the subblock level, the system can verify the erase subblock by subblock. Typically, if one of the subblocks fails, the system will go through the erase and verify again. Seeing that not all subblocks will pass the erase at the same time, the control logic can apply an inhibit voltage to passing subblocks on subsequent erase verify passes. An erase verify pass refers to one or more operations to apply an erase verify voltage to at least one wordline to verify an erase after the application of an erase voltage.

In one example, the system performs erase verify subblock by subblock, and increases the erase voltage on the next erase pulse. In one example, the process of applying the erase pulse, verifying the erase, and increasing the erase voltage will continue until all subblocks have passed the verify. In one example, the erase verify is performed separately for even and odd wordlines. Thus, the erase operation can be performed first one group of wordlines and subsequently on the other group.

Experimentation with storage devices has shown an increase the number of erase pulses needed, in on average, for all subblocks to pass the erase verify. For example, a storage device that initially needed 2 pulses for all subblocks to pass erase verify needed 3 erase pulses after 100 cycles. In addition to the number of erase pulses needed increasing from 2 to 3, the number of subblocks that failed after the first pulse continued to increase after 100 cycles. Applying an inhibit voltage to the passing wordlines can prevent more and more wordlines from being subject to erase pulse stress as the device ages.

In one example, logic that controls the erase process sets passing blocks to the an inhibit voltage to prevent another erase and verify being performed on those blocks. In one example, the logic sets passing blocks to a high voltage on subsequent erase and verify. The application of the high voltage can deselect the wordlines, and prevent them from receiving the erase pulse. Application of a voltage to passing wordlines to prevent them from being erased after a passing erase verify can reduce erase stress and reduce the spreading of Vt distribution.

It will be understood that a 3D storage device can have an SGS (select gate source) signal line at a bottom of a stack of storage cells, and an SGD (select gate drain) signal line at a top of the stack of storage cells. The storage cell stack includes multiple wordlines between the SGS and the SGD, which are selected by charge on a pillar or channel that runs vertically from the SGD through the SGS to the source. In one example, a 3D storage device can include a segmented SGS signal line, which effectively operates as separate SGS signal lines to control the operation of separate groups of storage cells stacks. A group can be referred to as a subblock.

The voltage differential or voltage delta between the SGD or SGS and the source can create a gate induced drain leakage (GIDL) current on the storage cells at the intersection of the channel with the wordlines. The GIDL current can exist for any storage cell stack where the SGS has a voltage differential to the source, whether all storage cell stacks share a common SGS in the block, or whether the block is divided into subblocks with segmented SGS signal lines. The system includes control circuitry that controls the voltages on the various signal lines. The control circuitry can change the voltage on either the SGD or the SGS or both for wordlines that have already passed erase verify. The change of the voltage can reduce the voltage delta, resulting in reduced GIDL current, which will cause minimal charge-up of the pillar, resulting in a weak erase effect to the subblock.

In one example, the application of the inhibit voltage refers to an inhibit voltage applied to an SGS line to prevent the charging of a pillar. In one example, the application of the inhibit voltage refers to the an inhibit voltage applied to an SGD line to prevent the charging of the pillar. In both cases the lack of charging the pillar can prevent the voltage differential that would cause erase or programming of the wordlines along the inhibited pillar. In one example, the application of the inhibit voltage refers to the application of an inhibit voltage to a wordline to prevent the specific wordline from having a voltage differential that would cause it to erase or program.

In one example, the erase will erase even and odd wordlines in separate passes. For example, the erase algorithm can verify even wordlines of every subblock and after verifying the even wordlines verify the odd wordlines, or vice-versa. With 3D stacks of storage cells, separation of the even and odd wordlines can reduce the amount of current needed for a given pass. With even and odd wordline separation, there can be advantages to performing an inhibit by separately inhibiting even/odd wordlines (depending on which is being verified). As a more specific example, consider that an erase algorithm first verifies even wordlines (WLs) followed by verification of the odd WLs. On a first pass for even WL erase verify, all odd WLs can be inhibited and all even WLs can be erased. For WLs that pass on the first erase, they will also be inhibited while the remaining even WLs are erased and verified again. After all even WLs have passed erase verify, the control logic could set all even WLs to inhibit and verify the odd WLs until they all pass, inhibiting odd WLs after each pass that passed on the previous iteration. In one example, once all even WLs have passed erase verify, the even WLs are set to a higher voltage (as limited by WL stress characteristics of the device) to then perform erase verify on the odd WLs.

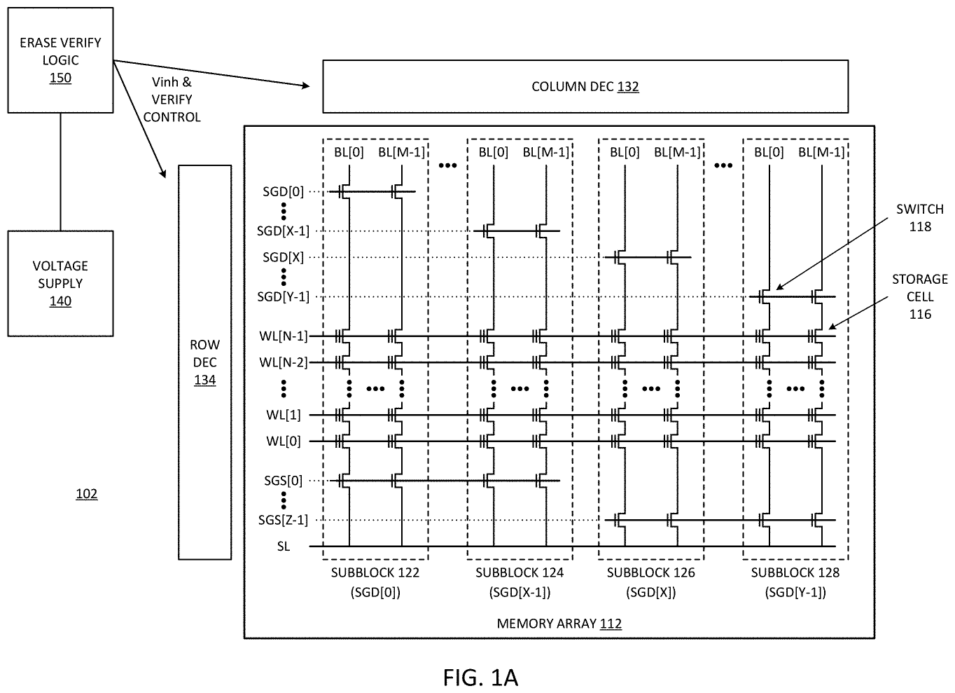

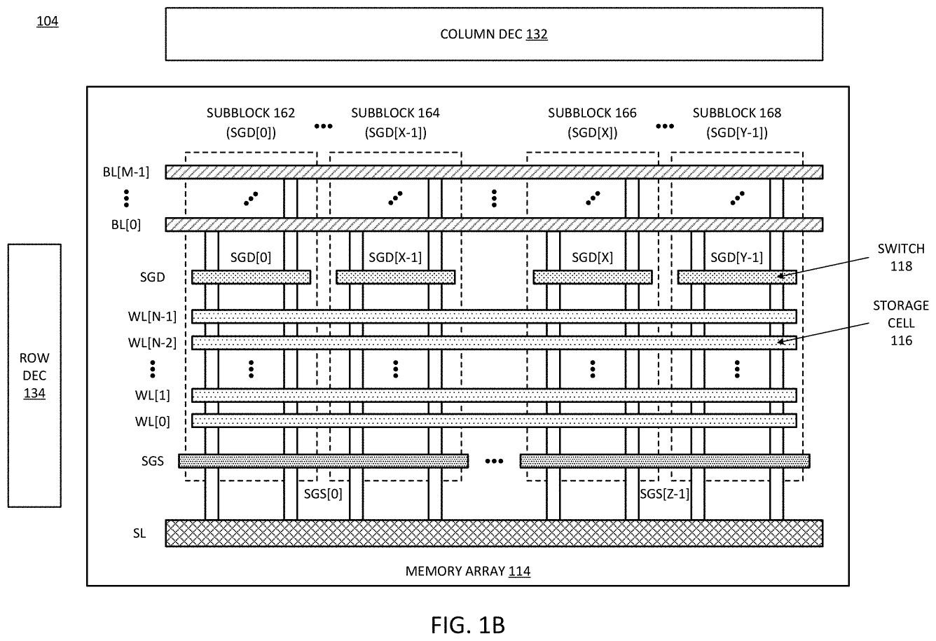

FIG. 1A is a block diagram of an example of a system having a memory device in which an erase verify can be performed in stages with selective wordline inhibit. System 102 represents a storage device in which erase verify selectively inhibits passing portions of the storage array. System 102 can be or be included in a solid state drive (SSD). System 102 can be integrated into a computing device.

System 100 includes memory array 110. In one example, memory array 110 represents a 3D NAND storage device. In one example, memory array 110 represents a 3D stacked memory device. In one example, the storage cells 116 represent NAND storage cells. In one example, storage cells 116 represent NOR-based storage cells.

Memory array 110 includes N wordlines (WL[0] to WL[N−1]). N can be, for example, 32, 48, 64, or some other number. In general, the size of memory array 110 and the number of wordlines in the stack do not affect the spread of Vt (threshold voltage) from over-erasing the storage cells. Over-erasing refers to performing an erase operation on a storage cell that already successfully erased on a previous iteration.

In one example, memory array 110 is segmented into subblocks. Subblocks 122, 124, 126, and 128 are illustrated, but are only to be understood as illustrative and not limiting. Segmentation of the memory array into different subblocks can include segmenting into any number of subblocks. An erase block refers to a portion of memory array 110 that is selected for erase. The erase block size is typically controlled by a host operating system, being a smallest unit size for access and programming. An erase block can include multiple subblocks.

In one example, a subblock refers to the columns, pillars, or strings of storage cells 116 that are accessed together. The pillars can be accessed to together by responding to a common switching signal. The switching signal can refer to gating control for the pillar. For example, the various pillars can be controlled by select gate drain (SGD) signal lines and select gate source (SGS) signal lines. An SGD signal line selectively couples a column to a bitline (BL). An SGS signal line selectively couples a column to a source line (SL). The source line (SL) can be a source layer of material integrated onto a semiconductor substrate.

In one example, each subblock includes M bitlines (BL[0] to BL[M−1]). In one example, each storage cell 116 within memory array 110 is addressed or selected by asserting a wordline and a bitline, in conjunction with enabling the column with the gate select switches 118 (shown only on SGD, but SGS switches can be considered included in the control).

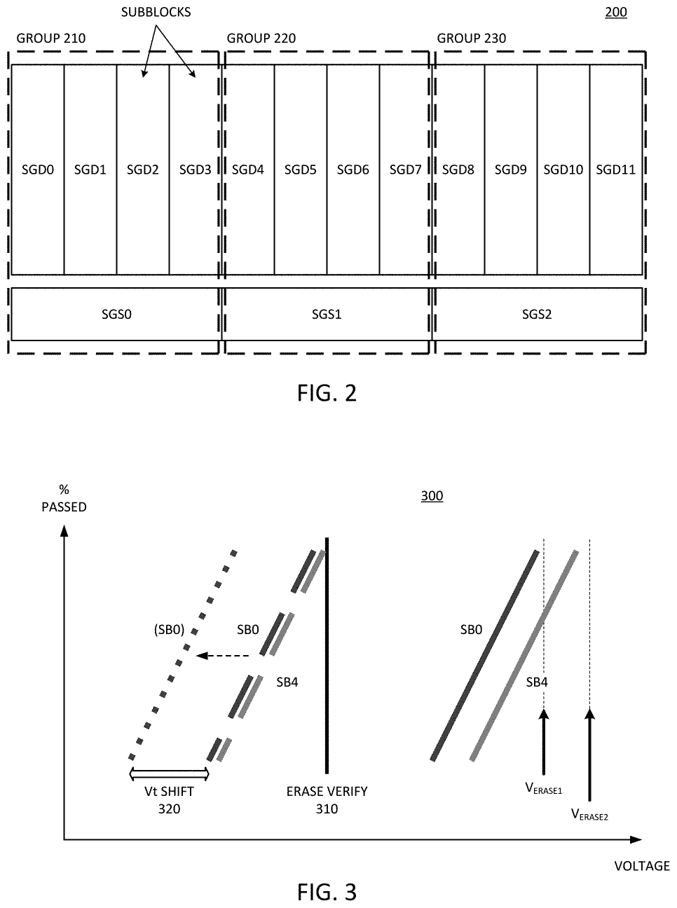

As specifically illustrated, memory array 110 includes SGD[0] to control selection of columns in subblock 122, SGD[X−1] to control selection of columns in subblock 124, SGD[X] to control selection of columns in subblock 126, and SGD[Y−1] to control selection of columns in subblock 128. In one example, multiple subblocks share a common source selection. Thus, for the Y SGD signal line illustrated, there are only Z SGS signal lines (SGS[0] to SGS[Z−1]), where Z is understood to be less than Y. In one example, memory array 110 includes the same number of SGS signal lines as SGD signal lines. As illustrated, SGD is segmented to provide separate control for the different subblocks, with one SGD segment per subblock. Likewise, SGS is segmented, with one SGS segment providing control for multiple subblocks (e.g., 4 subblocks as illustrated in FIG. 2, or some other number of subblocks).

System 102 includes column decode circuitry (column dec) 132 as a column address decoder to determine from a received command which bitline or bitlines to assert for a particular command. Row decode circuitry (row dec) 134 represents a row address decoder to determine from a received command which wordline or wordlines to assert for the command.

System 102 operates based on power received from voltage supply 140. Voltage supply 140 represents one or more voltage sources or voltage levels generated within system 102 to power electronic components of an electronic device, which can include system 102. Voltage supply 140 can generate different voltage levels, either as multiple voltage levels from a single voltage supply, or different voltage levels from different voltage supplies. Voltage supply 140 can generate multiple program voltages and an inhibit voltage.

System 102 includes circuitry to apply different voltage levels to different layers of the column stack. In one example, column decode 132 and row decode 134 provide circuitry to apply the various voltages to the various columns and layers of the stack. System 102 can include other circuitry to apply the voltages to the different signal lines or layers of the stack. For example, system 102 can apply high or low voltage levels to the select lines (e.g., SGS, SGD) or to various WLs, or to a combination of wordlines and select lines. The application of the voltages to the select lines can determine whether the switches are open or closed, thus selectively deselecting (open switches) or selecting (closed switches) the columns. The application of voltage to the WLs can determine whether the individual storage cells 116 receive charge, provide charge, or are shut off from the charge.

In one example, system 102 includes erase verify logic 150 couples to voltage supply 140. Erase verify logic 150 can provide erase and verify control to the various storage cells 116 of different wordlines or subblocks. Erase verify logic 150 also provides inhibit voltage to wordlines or subblocks that have already passed erase verify. It will be understood that the different voltage levels associated with program, erase, and inhibit can be dependent on the technology used to implement storage cells 116, and thus can be different from one implementation of system 102 to another. In general, voltage supply 140 provides voltage levels sufficient to program, read, or inhibit the storage cells. For programming the storage cells, voltage supply 140 provides voltage levels applied by column decode 132 and row decode 134 for charging or discharging individual storage cells to set the contents to a logic high or logic low. Voltage supply 140 provides voltage levels for read with column decode 132 and row decode 134 to enable detection of the value of storage cells 116. For inhibit, voltage supply 140 provides voltage levels applied by column decode 132 and row decode 134 to prevent the writing of one or more wordlines.

In an example where memory array 110 is a NAND array, erase verify logic 150 can be part of a NAND control unit (NCU). In one example, the NCU is implemented in a microcontroller on the NAND storage device such as a solid state drive (SSD). System 102 includes control logic to implement the erase verify control, including the setting of selected portions to an inhibit voltage. The control logic can be or include firmware that controls the erase algorithm. One or more parts of the erase algorithm can be implemented in hardware control logic. In general, the control logic is capable to provide the inhibit voltage as a different voltage on subsequent erase verify passes for portions that previously passed.

In one example, system 102 includes an SSD with memory array 110. One or more components of voltage supply 140 can be located outside the SSD, with the other elements of system 102 being within the SSD. In one example, portions of the voltage supply provide voltage to the SSD, and the SSD includes voltage supply hardware within the SSD to convert at least certain voltages to higher levels for program, erase, or inhibit. In one example, the main power supply provides multiple different voltage levels to the SSD, including erase and verify voltage levels. Whether the voltage control is within the SSD or outside the SSD, or in a different implementation of the storage device, the erase verify control logic provides feedback to the voltage control circuitry to generate other voltage levels for subsequent erase pulses.

FIG. 1B is a block diagram of an example of a circuit structure for the system of FIG. 1A. System 104 provides an example structure to implement a system in accordance with system 102 of FIG. 1A. The source line SL is common to all the subblocks, as are the wordlines (WL[0] to WL[N−1]). In one example, system 104 includes subblocks 162, 164, 166, and 168. Similar to system 104, the SGD layer is segmented. Subblock 162 is controlled by SGD[0], subblock 164 is controlled by SGD[X−1], subblock 166 is controlled by SGD[X], and subblock 168 is controlled by SGD[Y−1]. In one example, a storage cell 116 is formed at an intersection of a wordline and a bitline. In one example, a switch 118 is formed at an intersection of an SGD and a bitline and at the intersection of an SGS and a bitline.

The SGS layer is also segmented, with subblocks 162 and 164 controlled by SGS[0] and subblocks 166 and 168 controlled by SGS[Z−1]. It will be understood that system 104 can include any number of subblocks per SGS, and can include any number of SGS segments. Column decoder 132 provides control logic to select the various subblocks. Row decoder 134 provides control logic to apply different voltages to SGD, SGS, and the WLs. The voltages provide erase voltage and erase verify voltages for implementing erase verify in accordance with any example described herein.

FIG. 2 is a block diagram of an example of a memory device subblock architecture. Array 200 represents an example of a 3D NAND array structure. Array 200 provides one example of an array in accordance with memory array 110 of system 102. Array 200 illustrates an example where a memory array is subdivided into 12 subblocks, where 4 subblocks share a common SGS. As illustrated, a single subblock includes multiple wordlines (the WLs are not specifically illustrated) that share an SGD per subblock. As illustrated, several SGDs share an SGS in a group. The SGDs represent control switches that control access to a group of storage cells by connection to a bitline. The SGS represents control switches that control access to a group of storage cells by connection to the source (SRC).

More specifically, array 200 includes group 210, which is a group of subblocks. Array 200 also includes groups 220 and group 230. It will be understood that groups 210, 220, and 230 do not necessarily represent all of array 200, which can have additional subblocks and groups of subblocks. In one example, a group of subblocks represents an erase block to be erased together, where the erase verify occurs subblock by subblock in sequence until all subblocks pass the erase verify.

In one example, group 210 includes the subblocks for SGD0, SGD1, SGD2, and SGD3. The four subblocks of group 210 share a common SGS0. Group 220 includes the subblocks for SGD4, SGD5, SGD6, and SGD7 that share SGS1. Group 230 includes the subblocks for SGD8, SGD9, SGD10, and SGD11 that share SGS2. Array 220 can be referred to as having a segmented SGS, instead of having a common source gate select for the entire array. In one example, if SGD0-SGD7 pass erase verify, then in the next erase pulse, the control circuitry can set SGD0=SGD1= . . . =SGD7=SGS0=SGS1=SRC to inhibit the erase pulse on SGD0-SGD7. In such an example, SRC can be understood as a source layer common to all subblocks of array 200. In the example provided, setting the different select lines equal to each other and to the voltage of the source eliminates the voltage differential between the signal lines. The lack of the voltage different prevents the wordlines in the different subblocks from being erased. Setting an SGD=SRC refers to setting the gate or driving signal equal to the voltage of the SRC. For a transistor switch, setting the gate equal to SRC prevents a voltage differential between the gate and the drain, which prevents a channel from forming, inhibiting the flow of current through the channel.

In one example, the control logic can set an inhibit voltage for an SGD to inhibit the subblock on subsequent erase verify passes using higher erase voltage pulses. In one example, the control logic can set an inhibit voltage for an SGS to inhibit a group of subblocks on subsequent erase verify passes using higher erase voltage pulses. In one example, the control logic sets the inhibit voltage to both the SGS and SGD signal lines. In one example, the control logic does not set the control switches, but sets an inhibit voltage to the various WLs to inhibit them for subsequent erase verify passes using higher erase voltage pulses.

FIG. 3 is a diagram of an example of erase voltage distribution. In diagram 300, the dark line in the center represents erase verify voltage 310. Erase verify 310 represents a voltage used to perform erase verify of the storage cells on a given erase verify pass. In general, the erase operation occurs in a loop including the application of an erase voltage pulse and then performing an erase verify. As described herein, the system increases the erase voltage pulse for each subsequent erase verify pass. In one example, the erase verify voltage is fixed and is applied the same on each pass of the verify operation. A subblock passes erase verify when the application of erase verify voltage 310 does not result in a discharge, signifying that the cells have all been erased.

The solid lines on the right of diagram 300 represent the state of subblock SB0 and subblock SB4. Consider that a first erase pulse Verase1 is applied, which is high enough to reduce the cell Vt for the cells of SB0 to below erase verify 310. However, it will be observed that at least some of the cells of SB4 are not triggered by Verase1, which will result in an erase verify fail for SB4, while SB0 will pass erase verify.

Thus, consider two different scenarios. In a first scenario, SB0 has already passed erase verify on a previous pulse, but SB4 did not pass or was not yet erased. For a subsequent pass or a subsequent pulse, the control logic shifts the erase voltage higher to Verase2. At this voltage, SB4 will shift down below erase verify 310 and therefore will pass the erase verify.

However, under a traditional scenario, erase voltage Verase2 can also cause SB0 to shift down by some offset voltage illustrated as Vt shift 320. Vt shift 320 represents a Vt distribution variance between SB0 and SB4 that would result from erasing SB0 another time. Thus, there will be a larger distribution of Vt voltages for the various subblocks instead of having the Vt voltages closer in value.

In a second scenario, the control logic inhibits SB0 before the application of Verase2. The dark shaded dashed line represents the state of SB0 after the application of Verase2 when SB0 was inhibited. It will be observed that it is much closer to the state of SB4 than the other dashed line separated by Vt shift 320 that represents the traditional approach of not inhibiting SB0.

For purposes of illustration the light dashed line of SB4 and the dark dashed line of SB0 are shown right next to each other, while in a practical system there may be some variance or shift between them. However, the distribution will be much closer when SB0 is inhibited on the next pulse for SB4 than if Vt shift 320 occurs. The closer distribution of the Vt voltages results in lower coupling voltage, which results in less stress on the erase verify operations. Less erase stress in turn results in improved block reliability.

In general, without inhibiting SB0 after it passes erase verify, SB0 will shift by N*Verase_step until the storage cells of SB4 are below erase verify 310, where N represents the number of pulses more than SB0 that is takes for SB4 to pass erase verify and Verase_step represents an increase step of the erase voltage VeraseN, where N is an integer indicating which pass of the erase verify cycle the system is performing. If after SB0 passes the erase verify, the control logic inhibits SB0 for the subsequent pulse (e.g., by setting SGD0=SGS0=SRC), then the shift of SB0 is very small, as illustrated.

In one example, erase voltage Verase2 represents an erase voltage increased by 3.5 V over the previous pulse Verase1 (Verase_step=3.5 V). With differences of 3.5 V on the erase pulses, the inhibiting of the passing subblocks can reduce floating gate to floating gate (FG-FG) coupling by 175 mv on every edge.

In one example, only setting SGD=SRC does not weaken the erase pulse, and a different mechanism should be used to inhibit the subblocks. In one example, setting SGD=SGS=SRC provides better inhibit characteristics. In one example, inhibit individuals wordlines instead of inhibiting subblocks by the select switches provides improved performance.

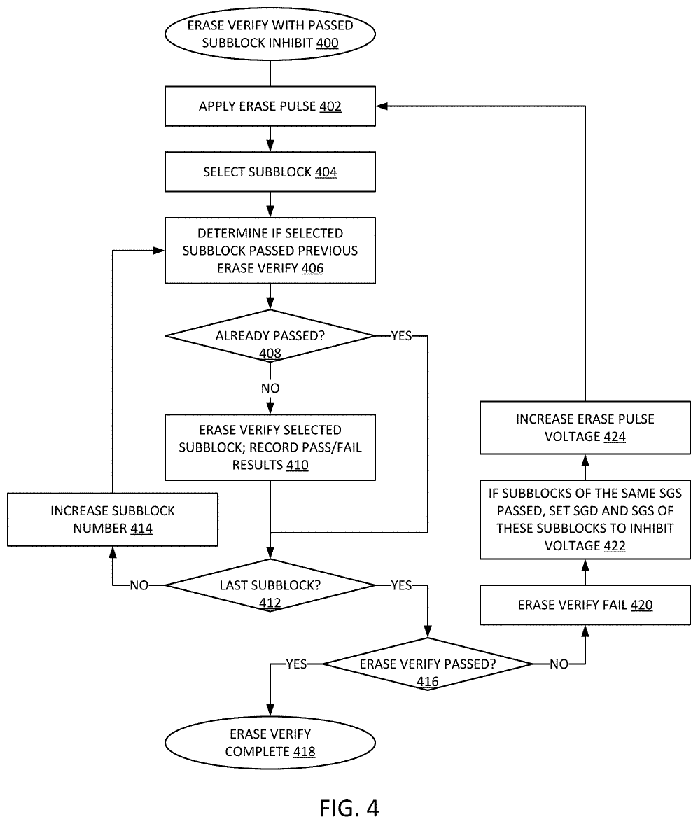

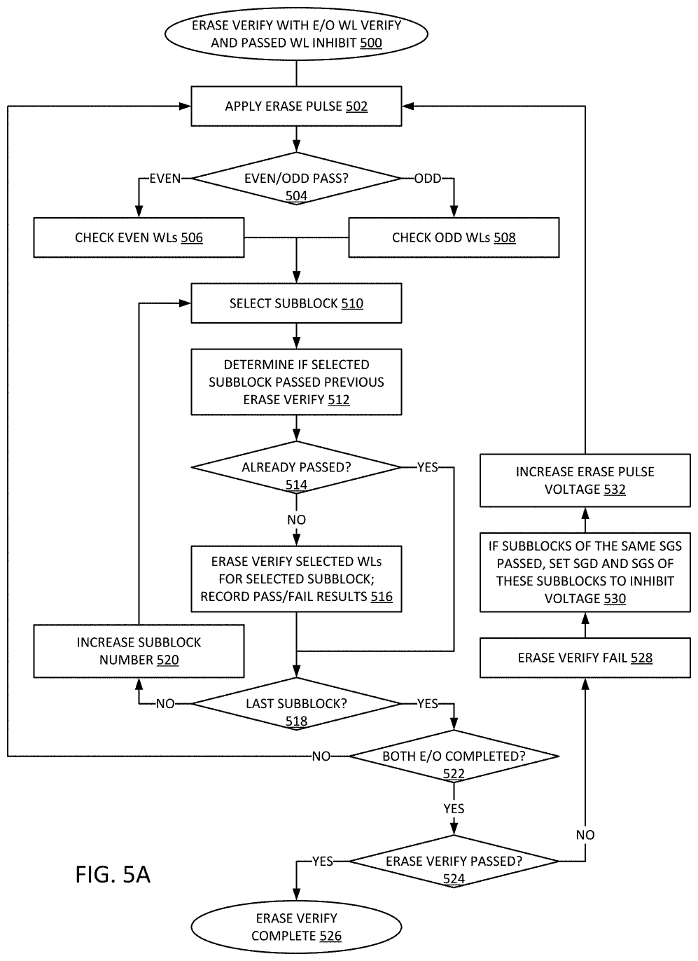

FIG. 4 is a flow diagram of an example of a process for providing erase verify with inhibit for passed subblocks. Process 400 represents a process executed by control logic that controls the erase operation in a storage device. Process 400 is a process for erase verify with passed subblock inhibit.

A system includes control circuitry that controls the application of voltage to the storage cells. When the system is going to perform an erase verify operation, the control circuitry can apply an erase pulse at an erase voltage to a block of storage cells to initiate the erase operation, at 402. The erase voltage is to trigger erase of the cells, which are then checked with an erase verify voltage. The logic that controls the erase verify operations and provides control signals to the control circuitry can select a subblock for erase verify, at 404. In one example, the logic determines if the selected subblock has passed a previous erase verify pass, at 406.

If the subblock has not already passed erase verify, at 408, NO branch, the logic can perform one or more operations to perform erase verify on the selected subblock, and record a pass/fail result for the operations, at 410. If the subblock has already passed erase verify, at 408, YES branch, in one example the logic will not perform erase verify for the subblock. When the erase verify for the selected subblock is either performed or skipped, the logic can determine if the selected subblock is the last subblock of the block for erase verify, at 412. Such a determination can be made in a configuration where multiple subblocks are verified in sequence or the logic iterates through erase verify in sequence on multiple subblocks.

If the selected subblock is not the last subblock, at 412, NO branch, the logic increases the subblock number for a subsequent subblock check, at 414. It will be understood that increasing subblock number is one way to select a subsequent subblock, but other methods could alternatively be performed such as decrementing or selecting in accordance with a round robin or other schedule. After selecting the next subblock for erase verify, the logic can loop back to determine if the subblock has already passed erase verify, at 406. If the subblock is the last subblock, at 412, YES branch, in one example, the logic then determines if erase verify has passed for the subblocks based on the results recorded, at 416.

If the subblocks all pass erase verify, at 416, YES branch, the erase verify is complete, at 418. If at least one subblock did not pass erase verify, at 416, NO branch, the logic determines that there was an erase verify fail, at 420. In one example, if subblocks of the same SGS passed, the logic optionally sets the SGD and SGS of the subblocks to the source voltage, at 422. The setting of subblocks or wordlines or both to the inhibit voltage can be performed in accordance with any example provided herein, which can include inhibiting an entire subblock, or a pillar, or individual wordlines, or a combination.

In one example, the logic increases the erase pulse voltage for a subsequent erase and erase verify pass, at 424. The logic will then loop through the erase verify again after application of the higher erase voltage with passing subblocks or wordlines set to an inhibit voltage to prevent those segments from being erased again. The logic loops back to 402 to apply the erase pulse and begin the erase verify operations.

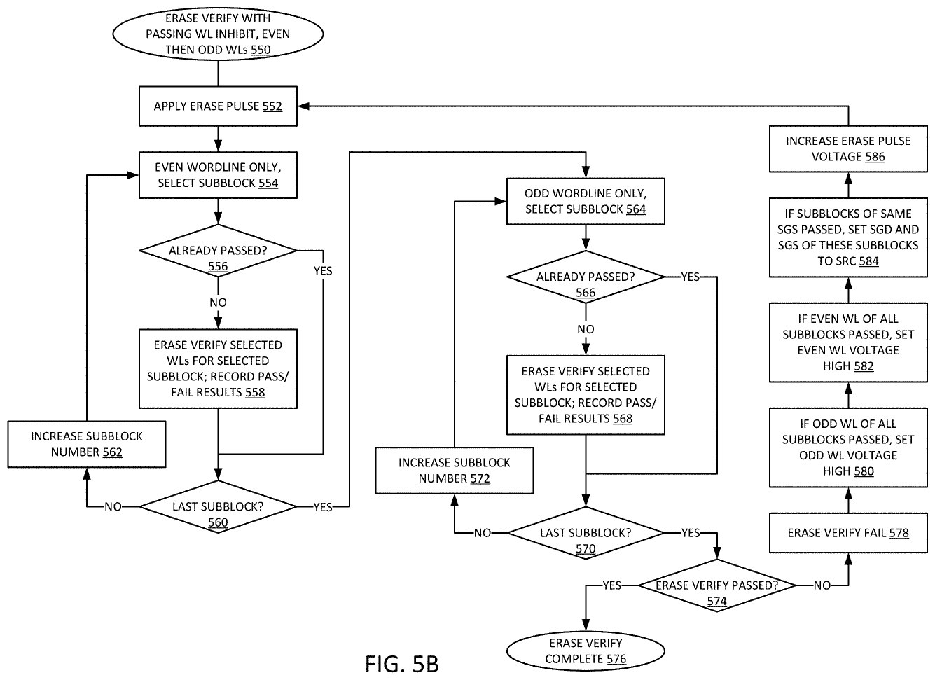

FIG. 5A is a flow diagram of an example of a process for providing erase verify with inhibit for passed wordlines with separate even and odd erase verify passes. Process 500 represents a process executed by control logic that controls the erase operation in a storage device. Process 500 is a process for erase verify with passed WL inhibit where even and odd wordlines (E/O WL) are verified separately. An implementation of a 3D NAND device can have relatively high resistance on the vertical pillars, which results in higher losses when charging the storage cells. Separating erase verify into even erase verify and odd erase verify can reduce the current needed to generate the erase voltages. Process 500 is one example of a process in accordance with process 400 of FIG. 4.

A system includes control circuitry that controls the application of voltage to the storage cells. When the system is going to perform an erase verify operation, the control circuitry can apply an erase pulse at an erase voltage to a block of storage cells to initiate the erase operation, at 502. The erase voltage is to trigger erase of the cells, which are then checked with an erase verify voltage. In one example, the system separately verifies even wordlines from odd wordlines. If the logic is performing an even wordline erase verify, at 504, EVEN branch, the logic performs erase verify on the even wordlines, at 506. If the logic is performing an odd wordline erase verify, at 504, ODD branch, the logic performs erase verify on the odd wordlines, at 508. While the selection and erase verify operations can be the same in either case, the even and odd wordlines are performed separately. In one example, the even wordlines are checked, subblock by subblock, followed by the odd wordlines, subblock by subblock. It will be understood that the order of even and odd can be reversed.

The logic that controls the erase verify operations and provides control signals to the control circuitry can select a subblock for erase verify, at 510. In one example, the logic determines if the selected subblock has passed a previous erase verify pass, at 512. If the subblock has not already passed erase verify, at 514, NO branch, the logic can perform one or more operations to perform erase verify on the selected subblock, and record a pass/fail result for the operations, at 516. If the subblock has already passed erase verify, at 514, YES branch, in one example the logic will not perform erase verify for the subblock. When the erase verify for the selected subblock is either performed or skipped, the logic can determine if the selected subblock is the last subblock of the block for erase verify, at 518. Such a determination can be made in a configuration where multiple subblocks are verified in sequence or the logic iterates through erase verify in sequence on multiple subblocks.

If the selected subblock is not the last subblock, at 518, NO branch, the logic increases the subblock number for a subsequent subblock check, at 520. It will be understood that increasing subblock number is one way to select a subsequent subblock, but other methods could alternatively be performed such as decrementing or selecting in accordance with a round robin or other schedule. After selecting the next subblock for erase verify, the logic can loop back to determine if the subblock has already passed erase verify, at 510. If the subblock is the last subblock, at 518, YES branch, in one example, the logic then determines if both the even and odd wordlines have completed erase verify, at 522.

If both even and odd wordlines have not completed erase verify, at 522, NO branch, in one example, the logic returns to 502 to perform erase verify on the other group of wordlines. Thus, if it started with even wordlines it will perform erase verify for odd wordlines. If it started with odd wordlines it will perform erase verify for even wordlines. If both even and odd wordlines have completed erase verify, at 522, YES branch, in one example, the logic determines if erase verify has passed for the subblocks based on the results recorded, at 524.

If the subblocks all pass erase verify, at 524, YES branch, the erase verify is complete, at 526. If at least one subblock did not pass erase verify, at 524, NO branch, the logic determines that there was an erase verify fail, at 528. In one example, if subblocks of the same SGS passed, the logic optionally sets the SGD and SGS of the subblocks to the source voltage, at 530. The setting of subblocks or wordlines or both to the inhibit voltage can be performed in accordance with any example provided herein, which can include inhibiting an entire subblock, or a pillar, or individual wordlines, or a combination. In one example, the ability to inhibit by wordline can benefit the system in performing even and odd wordlines separately. For example, the system can separately inhibit different groups of wordlines to perform separate even and odd erase verify passes.

In one example, the logic increases the erase pulse voltage for a subsequent erase and erase verify pass, at 532. The logic will then loop through the erase verify again after application of the higher erase voltage with passing subblocks or wordlines set to an inhibit voltage to prevent those segments from being erased again. The logic loops back to 502 to apply the erase pulse and begin the erase verify operations.

FIG. 5B is a flow diagram of an example of a process for providing erase verify with passing wordline inhibit, with separate even and odd wordline erase verify passes. Process 550 represents a process executed by control logic that controls the erase operation in a storage device. Process 550 is one example of a process in accordance with process 400 of FIG. 4.

Similar to process 500, the system can apply an erase pulse, at 552. In one example, the logic applies erase and erase verify to even wordlines only, subblock by subblock, at 554. It will be understood that the logic could reverse the order with odd wordlines first and even wordlines after. In one example, the logic determines if the selected subblock has passed a previous erase verify pass, at 556. If the subblock has not already passed erase verify, at 556, NO branch, the logic can perform one or more operations to perform erase verify on the selected subblock, and record a pass/fail result for the operations, at 558. If the subblock has already passed erase verify, at 556, YES branch, in one example the logic will not perform erase verify for the subblock. When the erase verify for the selected subblock is either performed or skipped, the logic can determine if the selected subblock is the last subblock of the block for erase verify, at 560. If the selected subblock is not the last subblock, at 560, NO branch, in one example the logic increases the subblock number for a subsequent erase verify, at 562. The logic loops back to select a subsequent subblock, at 554.

If the selected subblock is the last subblock, at 560, YES branch, in one example, the logic applies erase and erase verify to odd wordlines only, subblock by subblock, at 564. In one example, the logic determines if the odd wordlines of the selected subblock has passed a previous erase verify pass, at 566. If the subblock has not already passed erase verify, at 566, NO branch, the logic can perform one or more operations to perform erase verify on the selected subblock, and record a pass/fail result for the operations, at 568. If the subblock has already passed erase verify, at 566, YES branch, in one example the logic will not perform erase verify for the subblock. When the erase verify for the selected subblock is either performed or skipped, the logic can determine if the selected subblock is the last subblock of the block for erase verify, at 570. If the selected subblock is not the last subblock, at 570, NO branch, in one example the logic increases the subblock number for a subsequent erase verify, at 572. The logic loops back to select a subsequent subblock, at 564.

If the selected subblock is the last subblock, at 570, YES branch, then both even and odd wordlines have been checked. In one example, the logic then determines if erase verify has passed for the subblocks based on the results recorded, at 574. If the subblocks all pass erase verify, at 574, YES branch, the erase verify is complete, at 576. If at least one subblock did not pass erase verify, based on either the even or the odd pass, at 574, NO branch, the logic determines that there was an erase verify fail, at 578. In one example, if all odd wordlines of all subblocks passed erase verify, the logic sets the odd wordline voltage high, at 580. A high voltage is understood to inhibit the wordlines in this example. More generally, the odd wordlines can be set to an inhibit voltage. Similarly, in one example, if all even wordlines of all subblocks passed erase verify, the logic sets the even wordline voltage high (or to an inhibit voltage), at 582.

In one example, if subblocks of the same SGS passed, the logic optionally sets the SGD and SGS of the passing subblocks to the source voltage, at 584. In one example, the logic increases the erase pulse voltage for a subsequent erase and erase verify pass, at 586. The logic will then loop through the erase verify again after application of the higher erase voltage with passing subblocks or wordlines set to an inhibit voltage to prevent those segments from being erased again. The logic loops back to 552 to apply the erase pulse and begin the erase verify operations.

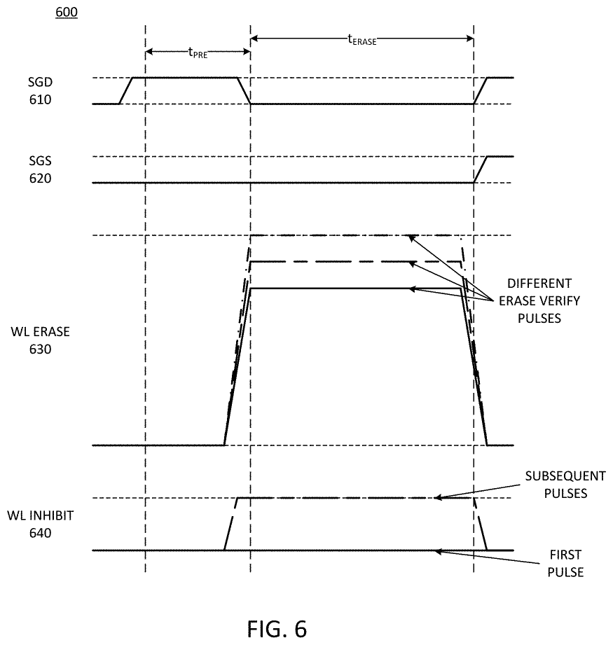

FIG. 6 is a diagrammatic representation of an embodiment of voltage waveforms in a system that provides wordline or subblock inhibit in for different stages of erase verify. Diagram 600 represents various voltage waveforms that could be present in a system that applies an inhibit voltage to storage cells that have already passed erase verify; thus, they are not erased again on a subsequent erase verify pass with the higher erase pulse.

It will be understood from diagram 600 that the voltage waveforms are not labeled with specific values, but can be understood as being relative to each other, and relative to a source layer. Thus, the low voltage rail of the different signals can be the voltage of a source (e.g., SRC). The slope of the voltages for ramp up and ramp down are not necessarily representative, but simply illustrate that a voltage level changes. The actual ramp up or ramp down could be some form of exponential curve, but for simplicity is illustrated as a straight line.

SGD 610 represents a source gate drain signal, which may be asserted to apply charge to the channel to access a storage cell. SGD 610 can couple the pillar through the channel conductor to a bitline. SGS 620 represents source gate select, which can couple the pillar to the source. SGS 620 can be asserted to discharge a storage cell.

WL erase 630 represents a voltage applied to a wordline selected for erase. The voltage for WL erase 630 can be provided as a pulse for an erase operation. The verify portion of the erase verify can be to read the storage cell or apply a voltage that will allow the system if charge flows out of the storage cell after erase. If no charge flows after the erase, the storage cell erased properly, and if charge flows out, the storage cell did not erase properly. WL inhibit 640 represents a voltage applied to a wordline to inhibit the wordline when an erase pulse is applied to another wordline for an erase operation.

Diagram 600 illustrates different erase pulses for WL erase 630. In one example, after one pass for erase verify, the system increases the erase voltage that appears on WL erase 630. A subsequent pass will have an even higher erase voltage. The system inhibits the wordlines that have passed erase verify. Thus, WL inhibit 640 is not asserted on the first pulse, and is asserted on subsequent pulses. It will be understood that even though WL erase 630 can increase with each pass, in one example, the erase verify voltage is a consistent target voltage that will not change from one pass to another. Thus, the same erase verify voltage can be used after each step up of the erase voltage until all wordlines or subblocks have passed erase verify.

In one example, the signals have a precharge period tPRE where SGD 610 is asserted to charge up the pillars. During tERASE the wordlines are charged to the erase voltage, and verify is subsequently performed by accessing the memory cells. The inhibit of the already verified wordlines can be in accordance with any example described, and reduces the erase stress of storage cells that erase sooner than other cells.

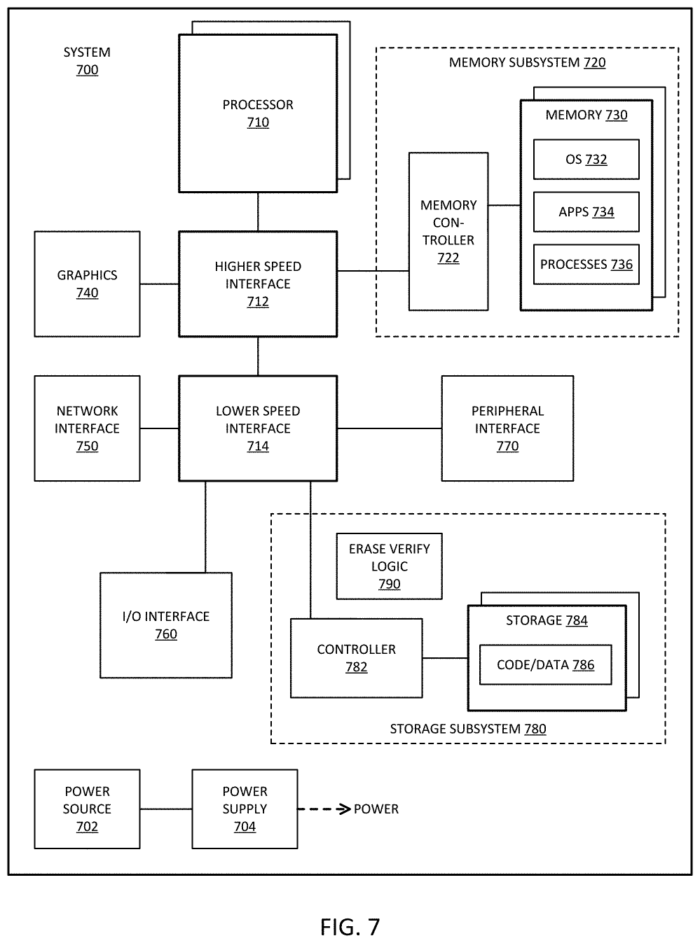

FIG. 7 is a block diagram of an example of a computing system in which erase verify with wordline or subblock inhibit can be implemented. System 700 represents a computing device in accordance with any example herein, and can be a laptop computer, a desktop computer, a tablet computer, a server, a gaming or entertainment control system, embedded computing device, or other electronic device.

In one example, system 700 includes erase verify logic 790 in storage subsystem 780. Erase verify logic 790 represents circuitry to perform erase verify operation in accordance with any example described. Erase verify logic 790 enables system 700 to inhibit passing wordlines or passing subblocks of storage 784 on subsequent erase verify passes. Erase verify logic 790 sets wordlines to an erase voltage, and wordlines that have already passed are inhibited to lower the erase stress on those wordlines.

System 700 includes processor 710 can include any type of microprocessor, central processing unit (CPU), graphics processing unit (GPU), processing core, or other processing hardware, or a combination, to provide processing or execution of instructions for system 700. Processor 710 controls the overall operation of system 700, and can be or include, one or more programmable general-purpose or special-purpose microprocessors, digital signal processors (DSPs), programmable controllers, application specific integrated circuits (ASICs), programmable logic devices (PLDs), or a combination of such devices.

In one example, system 700 includes interface 712 coupled to processor 710, which can represent a higher speed interface or a high throughput interface for system components that need higher bandwidth connections, such as memory subsystem 720 or graphics interface components 740. Interface 712 represents an interface circuit, which can be a standalone component or integrated onto a processor die. Interface 712 can be integrated as a circuit onto the processor die or integrated as a component on a system on a chip. Where present, graphics interface 740 interfaces to graphics components for providing a visual display to a user of system 700. Graphics interface 740 can be a standalone component or integrated onto the processor die or system on a chip. In one example, graphics interface 740 can drive a high definition (HD) display that provides an output to a user. In one example, the display can include a touchscreen display. In one example, graphics interface 740 generates a display based on data stored in memory 730 or based on operations executed by processor 710 or both.

Memory subsystem 720 represents the main memory of system 700, and provides storage for code to be executed by processor 710, or data values to be used in executing a routine. Memory subsystem 720 can include one or more memory devices 730 such as read-only memory (ROM), flash memory, one or more varieties of random access memory (RAM) such as DRAM, or other memory devices, or a combination of such devices. Memory 730 stores and hosts, among other things, operating system (OS) 732 to provide a software platform for execution of instructions in system 700. Additionally, applications 734 can execute on the software platform of OS 732 from memory 730. Applications 734 represent programs that have their own operational logic to perform execution of one or more functions. Processes 736 represent agents or routines that provide auxiliary functions to OS 732 or one or more applications 734 or a combination. OS 732, applications 734, and processes 736 provide software logic to provide functions for system 700. In one example, memory subsystem 720 includes memory controller 722, which is a memory controller to generate and issue commands to memory 730. It will be understood that memory controller 722 could be a physical part of processor 710 or a physical part of interface 712. For example, memory controller 722 can be an integrated memory controller, integrated onto a circuit with processor 710, such as integrated onto the processor die or a system on a chip.

While not specifically illustrated, it will be understood that system 700 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect (PCI) bus, a HyperTransport or industry standard architecture (ISA) bus, a small computer system interface (SCSI) bus, a universal serial bus (USB), or other bus, or a combination.

In one example, system 700 includes interface 714, which can be coupled to interface 712. Interface 714 can be a lower speed interface than interface 712. In one example, interface 714 represents an interface circuit, which can include standalone components and integrated circuitry. In one example, multiple user interface components or peripheral components, or both, couple to interface 714. Network interface 750 provides system 700 the ability to communicate with remote devices (e.g., servers or other computing devices) over one or more networks. Network interface 750 can include an Ethernet adapter, wireless interconnection components, cellular network interconnection components, USB (universal serial bus), or other wired or wireless standards-based or proprietary interfaces. Network interface 750 can exchange data with a remote device, which can include sending data stored in memory or receiving data to be stored in memory.

In one example, system 700 includes one or more input/output (I/O) interface(s) 760. I/O interface 760 can include one or more interface components through which a user interacts with system 700 (e.g., audio, alphanumeric, tactile/touch, or other interfacing). Peripheral interface 770 can include any hardware interface not specifically mentioned above. Peripherals refer generally to devices that connect dependently to system 700. A dependent connection is one where system 700 provides the software platform or hardware platform or both on which operation executes, and with which a user interacts.

In one example, system 700 includes storage subsystem 780 to store data in a nonvolatile manner. In one example, in certain system implementations, at least certain components of storage 780 can overlap with components of memory subsystem 720. Storage subsystem 780 includes storage device(s) 784, which can be or include any conventional medium for storing large amounts of data in a nonvolatile manner, such as one or more magnetic, solid state, or optical based disks, or a combination. Storage 784 holds code or instructions and data 786 in a persistent state (i.e., the value is retained despite interruption of power to system 700). Storage 784 can be generically considered to be a “memory,” although memory 730 is typically the executing or operating memory to provide instructions to processor 710. Whereas storage 784 is nonvolatile, memory 730 can include volatile memory (i.e., the value or state of the data is indeterminate if power is interrupted to system 700). In one example, storage subsystem 780 includes controller 782 to interface with storage 784. In one example controller 782 is a physical part of interface 714 or processor 710, or can include circuits or logic in both processor 710 and interface 714.

Power source 702 provides power to the components of system 700. More specifically, power source 702 typically interfaces to one or multiple power supplies 704 in system 702 to provide power to the components of system 700. In one example, power supply 704 includes an AC to DC (alternating current to direct current) adapter to plug into a wall outlet. Such AC power can be renewable energy (e.g., solar power) power source 702. In one example, power source 702 includes a DC power source, such as an external AC to DC converter. In one example, power source 702 or power supply 704 includes wireless charging hardware to charge via proximity to a charging field. In one example, power source 702 can include an internal battery or fuel cell source.

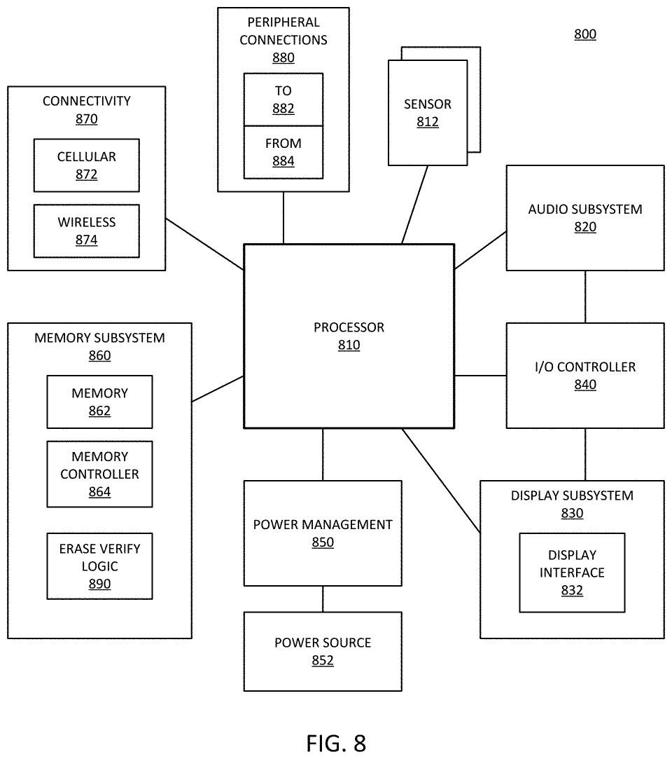

FIG. 8 is a block diagram of an example of a mobile device in which erase verify with wordline or subblock inhibit can be implemented. Device 800 represents a mobile computing device, such as a computing tablet, a mobile phone or smartphone, wearable computing device, or other mobile device, or an embedded computing device. It will be understood that certain of the components are shown generally, and not all components of such a device are shown in device 800.

In one example, system 800 includes erase verify logic 890 in memory subsystem 860 to manage erase verify of nonvolatile storage that is erased. Erase verify logic 890 represents circuitry to perform erase verify operation in accordance with any example described. Erase verify logic 890 enables system 800 to inhibit passing wordlines or passing subblocks of a nonvolatile storage of memory 862 on subsequent erase verify passes. Erase verify logic 890 sets wordlines to an erase voltage, and wordlines that have already passed are inhibited to lower the erase stress on those wordlines.

Device 800 includes processor 810, which performs the primary processing operations of device 800. Processor 810 can include one or more physical devices, such as microprocessors, application processors, microcontrollers, programmable logic devices, or other processing means. The processing operations performed by processor 810 include the execution of an operating platform or operating system on which applications and device functions are executed. The processing operations include operations related to I/O (input/output) with a human user or with other devices, operations related to power management, operations related to connecting device 800 to another device, or a combination. The processing operations can also include operations related to audio I/O, display I/O, or other interfacing, or a combination. Processor 810 can execute data stored in memory. Processor 810 can write or edit data stored in memory.

In one example, system 800 includes one or more sensors 812. Sensors 812 represent embedded sensors or interfaces to external sensors, or a combination. Sensors 812 enable system 800 to monitor or detect one or more conditions of an environment or a device in which system 800 is implemented. Sensors 812 can include environmental sensors (such as temperature sensors, motion detectors, light detectors, cameras, chemical sensors (e.g., carbon monoxide, carbon dioxide, or other chemical sensors)), pressure sensors, accelerometers, gyroscopes, medical or physiology sensors (e.g., biosensors, heart rate monitors, or other sensors to detect physiological attributes), or other sensors, or a combination. Sensors 812 can also include sensors for biometric systems such as fingerprint recognition systems, face detection or recognition systems, or other systems that detect or recognize user features. Sensors 812 should be understood broadly, and not limiting on the many different types of sensors that could be implemented with system 800. In one example, one or more sensors 812 couples to processor 810 via a frontend circuit integrated with processor 810. In one example, one or more sensors 812 couples to processor 810 via another component of system 800.

In one example, device 800 includes audio subsystem 820, which represents hardware (e.g., audio hardware and audio circuits) and software (e.g., drivers, codecs) components associated with providing audio functions to the computing device. Audio functions can include speaker or headphone output, as well as microphone input. Devices for such functions can be integrated into device 800, or connected to device 800. In one example, a user interacts with device 800 by providing audio commands that are received and processed by processor 810.

Display subsystem 830 represents hardware (e.g., display devices) and software components (e.g., drivers) that provide a visual display for presentation to a user. In one example, the display includes tactile components or touchscreen elements for a user to interact with the computing device. Display subsystem 830 includes display interface 832, which includes the particular screen or hardware device used to provide a display to a user. In one example, display interface 832 includes logic separate from processor 810 (such as a graphics processor) to perform at least some processing related to the display. In one example, display subsystem 830 includes a touchscreen device that provides both output and input to a user. In one example, display subsystem 830 includes a high definition (HD) or ultra-high definition (UHD) display that provides an output to a user. In one example, display subsystem includes or drives a touchscreen display. In one example, display subsystem 830 generates display information based on data stored in memory or based on operations executed by processor 810 or both.

I/O controller 840 represents hardware devices and software components related to interaction with a user. I/O controller 840 can operate to manage hardware that is part of audio subsystem 820, or display subsystem 830, or both. Additionally, I/O controller 840 illustrates a connection point for additional devices that connect to device 800 through which a user might interact with the system. For example, devices that can be attached to device 800 might include microphone devices, speaker or stereo systems, video systems or other display device, keyboard or keypad devices, or other I/O devices for use with specific applications such as card readers or other devices.

As mentioned above, I/O controller 840 can interact with audio subsystem 820 or display subsystem 830 or both. For example, input through a microphone or other audio device can provide input or commands for one or more applications or functions of device 800. Additionally, audio output can be provided instead of or in addition to display output. In another example, if display subsystem includes a touchscreen, the display device also acts as an input device, which can be at least partially managed by I/O controller 840. There can also be additional buttons or switches on device 800 to provide I/O functions managed by I/O controller 840.

In one example, I/O controller 840 manages devices such as accelerometers, cameras, light sensors or other environmental sensors, gyroscopes, global positioning system (GPS), or other hardware that can be included in device 800, or sensors 812. The input can be part of direct user interaction, as well as providing environmental input to the system to influence its operations (such as filtering for noise, adjusting displays for brightness detection, applying a flash for a camera, or other features).

In one example, device 800 includes power management 850 that manages battery power usage, charging of the battery, and features related to power saving operation. Power management 850 manages power from power source 852, which provides power to the components of system 800. In one example, power source 852 includes an AC to DC (alternating current to direct current) adapter to plug into a wall outlet. Such AC power can be renewable energy (e.g., solar power, motion based power). In one example, power source 852 includes only DC power, which can be provided by a DC power source, such as an external AC to DC converter. In one example, power source 852 includes wireless charging hardware to charge via proximity to a charging field. In one example, power source 852 can include an internal battery or fuel cell source.

Memory subsystem 860 includes memory device(s) 862 for storing information in device 800. Memory subsystem 860 can include nonvolatile (state does not change if power to the memory device is interrupted) or volatile (state is indeterminate if power to the memory device is interrupted) memory devices, or a combination. Memory 860 can store application data, user data, music, photos, documents, or other data, as well as system data (whether long-term or temporary) related to the execution of the applications and functions of system 800. In one example, memory subsystem 860 includes memory controller 864 (which could also be considered part of the control of system 800, and could potentially be considered part of processor 810). Memory controller 864 includes a scheduler to generate and issue commands to control access to memory device 862.

Connectivity 870 includes hardware devices (e.g., wireless or wired connectors and communication hardware, or a combination of wired and wireless hardware) and software components (e.g., drivers, protocol stacks) to enable device 800 to communicate with external devices. The external device could be separate devices, such as other computing devices, wireless access points or base stations, as well as peripherals such as headsets, printers, or other devices. In one example, system 800 exchanges data with an external device for storage in memory or for display on a display device. The exchanged data can include data to be stored in memory, or data already stored in memory, to read, write, or edit data.

Connectivity 870 can include multiple different types of connectivity. To generalize, device 800 is illustrated with cellular connectivity 872 and wireless connectivity 874. Cellular connectivity 872 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, LTE (long term evolution—also referred to as “4G”), or other cellular service standards. Wireless connectivity 874 refers to wireless connectivity that is not cellular, and can include personal area networks (such as Bluetooth), local area networks (such as WiFi), or wide area networks (such as WiMax), or other wireless communication, or a combination. Wireless communication refers to transfer of data through the use of modulated electromagnetic radiation through a non-solid medium. Wired communication occurs through a solid communication medium.

Peripheral connections 880 include hardware interfaces and connectors, as well as software components (e.g., drivers, protocol stacks) to make peripheral connections. It will be understood that device 800 could both be a peripheral device (“to” 882) to other computing devices, as well as have peripheral devices (“from” 884) connected to it. Device 800 commonly has a “docking” connector to connect to other computing devices for purposes such as managing (e.g., downloading, uploading, changing, synchronizing) content on device 800. Additionally, a docking connector can allow device 800 to connect to certain peripherals that allow device 800 to control content output, for example, to audiovisual or other systems.

In addition to a proprietary docking connector or other proprietary connection hardware, device 800 can make peripheral connections 880 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), or other type.

In general with respect to the descriptions herein, in one example an apparatus includes a storage array including a three-dimensional (3D) stack of storage cells, wherein signal lines of the 3D stack are capable to receive separate voltages for an erase operation including either an erase voltage or an inhibit voltage; and control logic to perform an erase verify for an erase block of the storage array, including for a first erase pulse to set a first erase voltage for storage cells of the 3D stack, and for a second erase pulse to set the inhibit voltage for storage cells that passed on the first erase pulse and set a second erase voltage higher than the first voltage for storage cells that failed on the first erase pulse.

In one example, the erase block comprises a subblock, where multiple subblocks are to be verified in sequence. In one example, the subblock comprises a group of multiple 3D stacks of storage cells controlled by a common SGD (select gate drain) signal, and wherein to perform the erase verify comprises the control logic to perform erase verify on multiple subblocks having separate SGD signals and a common SGS (select gate source) signal. In one example, the control logic is to perform erase verify on even wordlines separately from odd wordlines. In one example, the control logic is to set the inhibit voltage for an SGD (select gate drain) signal line of the 3D stack. In one example, the control logic is to set the inhibit voltage fora common SGS (select gate source) signal line of the 3D stack. In one example, the control logic is to set the inhibit voltage for wordlines of the 3D stack. In one example, the second erase voltage comprises a voltage 3.5 V higher than the first erase voltage. In one example, the control logic to further generate a third erase pulse with a third erase voltage higher than the second erase voltage, and for the third erase pulse to set the inhibit voltage for storage cells that passed on the first or second erase pulses and set the third erase voltage for storage cells that failed on the second erase pulse. In one example, the 3D stack comprises a stack of 3D NAND storage cells.

In general with respect to the descriptions herein, in one example a system includes: a voltage supply to generate a voltage; and a solid state drive (SSD) including circuitry to receive the voltage and generate an erase voltage and an inhibit voltage; a storage array including a three-dimensional (3D) stack of storage cells; and control logic to perform an erase verify for an erase block of the storage array, including for a first erase pulse to set a first erase voltage for storage cells of the 3D stack, and for a second erase pulse to set the inhibit voltage for storage cells that passed on the first erase pulse and set a second erase voltage higher than the first voltage for storage cells that failed on the first erase pulse.

For the system, the examples with respect to the apparatus apply to the system as well. In one example, the system further includes one or more of: a host processor device coupled to the SSD; a display communicatively coupled to a host processor; a network interface communicatively coupled to a host processor; or a battery to power the system.

Flow diagrams as illustrated herein provide examples of sequences of various process actions. The flow diagrams can indicate operations to be executed by a software or firmware routine, as well as physical operations. A flow diagram can illustrate an example of the implementation of states of a finite state machine (FSM), which can be implemented in hardware and/or software. Although shown in a particular sequence or order, unless otherwise specified, the order of the actions can be modified. Thus, the illustrated diagrams should be understood only as examples, and the process can be performed in a different order, and some actions can be performed in parallel. Additionally, one or more actions can be omitted; thus, not all implementations will perform all actions.

To the extent various operations or functions are described herein, they can be described or defined as software code, instructions, configuration, and/or data. The content can be directly executable (“object” or “executable” form), source code, or difference code (“delta” or “patch” code). The software content of what is described herein can be provided via an article of manufacture with the content stored thereon, or via a method of operating a communication interface to send data via the communication interface. A machine readable storage medium can cause a machine to perform the functions or operations described, and includes any mechanism that stores information in a form accessible by a machine (e.g., computing device, electronic system, etc.), such as recordable/non-recordable media (e.g., read only memory (ROM), random access memory (RAM), magnetic disk storage media, optical storage media, flash memory devices, etc.). A communication interface includes any mechanism that interfaces to any of a hardwired, wireless, optical, etc., medium to communicate to another device, such as a memory bus interface, a processor bus interface, an Internet connection, a disk controller, etc. The communication interface can be configured by providing configuration parameters and/or sending signals to prepare the communication interface to provide a data signal describing the software content. The communication interface can be accessed via one or more commands or signals sent to the communication interface.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, etc.

Besides what is described herein, various modifications can be made to what is disclosed and implementations of the invention without departing from their scope. Therefore, the illustrations and examples herein should be construed in an illustrative, and not a restrictive sense. The scope of the invention should be measured solely by reference to the claims that follow.

What is claimed is:

1. An apparatus, comprising:
a storage array including a three-dimensional (3D) stack of storage cells, wherein signal lines of the 3D stack are capable to receive separate voltages for an erase operation including either an erase voltage or an inhibit voltage; and
control logic to perform an erase verify for an erase block of the storage array, including for a first erase pulse to set a first erase voltage for storage cells of the 3D stack, and for a second erase pulse to set the inhibit voltage for storage cells that passed on the first erase pulse and set a second erase voltage higher than the first voltage for storage cells that failed on the first erase pulse.

2. The apparatus of claim 1, wherein the erase block comprises a subblock, where multiple subblocks are to be verified in sequence.

3. The apparatus of claim 2, wherein the subblock comprises a group of multiple 3D stacks of storage cells controlled by a common SGD (select gate drain) signal, and wherein to perform the erase verify comprises the control logic to perform erase verify on multiple subblocks having separate SGD signals and a common SGS (select gate source) signal.

4. The apparatus of claim 1, wherein the control logic is to perform erase verify on even wordlines separately from odd wordlines.

5. The apparatus of claim 1, wherein the control logic is to set the inhibit voltage for an SGD (select gate drain) signal line of the 3D stack.

6. The apparatus of claim 1, wherein the control logic is to set the inhibit voltage for a common SGS (select gate source) signal line of the 3D stack.

7. The apparatus of claim 1, wherein the control logic is to set the inhibit voltage for wordlines of the 3D stack.

8. The apparatus of claim 1, wherein the second erase voltage comprises a voltage 3.5 V higher than the first erase voltage.

9. The apparatus of claim 1, comprising the control logic to further generate a third erase pulse with a third erase voltage higher than the second erase voltage, and for the third erase pulse to set the inhibit voltage for storage cells that passed on the first or second erase pulses and set the third erase voltage for storage cells that failed on the second erase pulse.

10. The apparatus of claim 1, wherein the 3D stack comprises a stack of 3D NAND storage cells.

11. A system, comprising:
a voltage supply to generate a voltage; and
a solid state drive (SSD) including
circuitry to receive the voltage and generate an erase voltage and an inhibit voltage;
a storage array including a three-dimensional (3D) stack of storage cells; and
control logic to perform an erase verify for an erase block of the storage array, including for a first erase pulse to set a first erase voltage for storage cells of the 3D stack, and for a second erase pulse to set the inhibit voltage for storage cells that passed on the first erase pulse and set a second erase voltage higher than the first voltage for storage cells that failed on the first erase pulse.

12. The system of claim 11, wherein the erase block comprises a subblock, where multiple subblocks are to be verified in sequence.

13. The system of claim 12, wherein the subblock comprises a group of multiple 3D stacks of storage cells controlled by a common SGD (select gate drain) signal, and wherein to perform the erase verify comprises the control logic to perform erase verify on multiple subblocks having separate SGD signals and a common SGS (select gate source) signal.

14. The system of claim 11, wherein the control logic is to perform erase verify on even wordlines separately from odd wordlines.

15. The system of claim 11, wherein the control logic is to set the inhibit voltage for an SGD (select gate drain) signal line of the 3D stack.

16. The system of claim 11, wherein the control logic is to set the inhibit voltage for a common SGS (select gate source) signal line of the 3D stack.

17. The system of claim 11, wherein the control logic is to set the inhibit voltage for wordlines of the 3D stack.

18. The system of claim 11, wherein the second erase voltage comprises a voltage 3.5 V higher than the first erase voltage.

19. The system of claim 11, comprising the control logic to further generate a third erase pulse with a third erase voltage higher than the second erase voltage, and for the third erase pulse to set the inhibit voltage for storage cells that passed on the first or second erase pulses and set the third erase voltage for storage cells that failed on the second erase pulse.

20. The system of claim 11, wherein the 3D stack comprises a stack of 3D NAND storage cells.

21. The system of claim 11, further comprising one or more of:
a host processor device coupled to the SSD;
a display communicatively coupled to a host processor;
a network interface communicatively coupled to a host processor; or
a battery to power the system.
